(19) United States
(12) Patent Application Publication
(10) Pub. No.: US 2014/0370699 A1
(43) Pub. Date: Dec. 18, 2014

(54) METHOD FOR FABRICATING SEMICONDUCTOR DEVICE

(71) Applicants: Ju-Youn Kim, Suwon-si (KR); Chul-Woong Lee, Suwon-si (KR); Tae-Sun Kim, Hwaseong-si (KR); Sang-Duk Park, Hwaseong-si (KR); Bum-Joon Youn, Suwon-si (KR); Tae-Won Ha, Seongnam-si (KR)

(72) Inventors: Ju-Youn Kim, Suwon-si (KR); Chul-Woong Lee, Suwon-si (KR); Tae-Sun Kim, Hwaseong-si (KR); Sang-Duk Park, Hwaseong-si (KR); Bum-Joon Youn, Suwon-si (KR); Tae-Won Ha, Seongnam-si (KR)

(21) Appl. No.: 14/145,188

(22) Filed: Dec. 31, 2013

(30) Foreign Application Priority Data
Jun. 13, 2013 (KR) 10-2013-0067851

(51) Int. Cl. H01L 21/308; H01L 21/28

(52) U.S. Cl. CPC H01L 21/308; H01L 21/28008
USPC 438/587

(57) ABSTRACT

A method of fabricating a semiconductor device includes forming an interlayer insulating layer on a substrate, the interlayer insulating layer including a first trench and a second trench, forming a first conductive layer along sidewall surfaces and bottom surface of the first trench and forming a second conductive layer along sidewall surfaces and bottom surface of the second trench, forming a mask pattern on the second conductive layer, the mask pattern filling the second trench and being a bottom anti-reflective coating (BARC), and removing the first conductive layer using the mask pattern.

### CROSS-REFERENCE TO RELATED APPLICATION

This application claims priority from Korean Patent Application No. 10-2013-0067851 filed on Jun. 13, 2013 in the Korean Intellectual Property Office, and all the benefits accruing therefrom under 35 U.S.C. 119, the content of which in its entirety is herein incorporated by reference.

### BACKGROUND

1. Field

Embodiments of the present inventive concepts relate to a method for fabricating a semiconductor device.

2. Description of Related Art

In recent years, in an effort to improve characteristics of a semiconductor device, it has become popular to replace a metal gate with a polysilicon gate. In some applications, the metal gate can be formed using a replacement metal gate process.

With increased popularity and functionality of electronic devices, there is industry pressure toward further integration and increased density of a semiconductor device. In a scaled-down semiconductor device, the replacement metal gate process requires multiple cycles of etching, deposition and grinding steps. This leads to increased costs and reduced yield.

### SUMMARY

Embodiments of the present inventive concepts provide a method for fabricating a semiconductor device, which can improve the yield of semiconductor devices.

The above and other objects of the present inventive concepts will be described in or be apparent from the following description of embodiments.

In one aspect, a method for fabricating a semiconductor device comprises: forming an interlayer insulating layer on a substrate, the interlayer insulating layer including a first trench and a second trench; forming a first conductive layer along sidewall surfaces and a bottom surface of the first trench and forming a second conductive layer along sidewall surfaces and a bottom surface of the second trench; forming a mask pattern on the second conductive layer, the mask pattern filling the second trench and comprising a bottom anti-reflective coating (BARC); and removing the first conductive layer using the mask pattern.

In some embodiments, the forming of the mask pattern comprises forming a mask layer filling the first trench and the second trench on the first conductive layer and the second conductive layer, and removing the mask layer filling the first trench using a mixed gas including oxygen and chlorine.

In some embodiments, the forming of the mask pattern comprises removing the mask layer filling the first trench by reactive ion etching (RIE).

In some embodiments, the first conductive layer and the second conductive layer directly contacts the mask layer.

In some embodiments, the forming of the mask pattern comprises forming a photoresist film pattern on the mask layer, the photoresist film pattern on the second conductive layer and not on the first conductive layer, and removing the mask layer filling the first trench using the photoresist film pattern.

In some embodiments, the removing of the first conductive layer comprises removing the first conductive layer formed along the sidewall surfaces and bottom surface of the first trench using a stack of the photoresist film pattern and the mask pattern.

In some embodiments, the forming of the mask pattern comprises forming the mask pattern filling the first trench and the second trench on the first conductive layer and the second conductive layer, and removing the mask pattern filling the first trench using a mixed gas including oxygen and chlorine.

In some embodiments, the first trench is formed on an NMOS region and the second trench is formed on a PMOS region.

In some embodiments, the first conductive layer and the second conductive layer comprise TiN.

In some embodiments, the forming of the first conductive layer and the second conductive layer comprises simultaneously forming the first conductive layer and the second conductive layer along a top surface of the interlayer insulating layer, sidewall surfaces and bottom surface of the first trench and sidewall surfaces and bottom surface of the second trench.

In some embodiments, the forming of the first trench and the second trench comprises forming a first dummy gate and a second dummy gate on the substrate, the first dummy gate and the second dummy gate formed on a first region and a second region of the substrate, respectively, forming the interlayer insulating layer covering the first dummy gate and the second dummy gate on the substrate, exposing the first dummy gate and the second dummy gate by planarizing the interlayer insulating layer, and removing the first dummy gate and the second dummy gate.

In some embodiments, a first gate dielectric layer is positioned between the first dummy gate and the substrate, and a second gate dielectric layer is positioned between the second dummy gate and the substrate.

In some embodiments, the forming of the first conductive layer comprises forming the first conductive layer on the top surface of the interlayer insulating layer, the sidewall surface of the first trench and the top surface of the first gate dielectric layer, and the forming of the second conductive layer comprises forming the second conductive layer on the top surface of the interlayer insulating layer, the sidewall surface of the second trench and the top surface of the second gate dielectric layer.

In some embodiments, after the removing of the first dummy gate and the second dummy gate, further comprising removing the first gate dielectric layer and the second gate dielectric layer, and before the forming of the first conductive layer and the second conductive layer, further comprising forming a dielectric layer on the top surface of the interlayer insulating layer, the sidewall surfaces and bottom surface of the first trench and the sidewall surfaces and bottom surface of the second trench.

In an aspect, a method for fabricating a semiconductor device comprises: forming an interlayer insulating layer on a substrate, the interlayer insulating layer including a first trench and a second trench; forming a first conductive layer along sidewall surfaces and a bottom surface of the first trench and forming a second conductive layer along sidewall surfaces and bottom surface of the second trench; forming a mask layer on the first conductive layer and the second conductive layer, the mask layer filling the first trench and the second trench; forming a photoresist film pattern on the mask layer, the photoresist film pattern exposing the mask layer formed on the first conductive layer; forming a mask pattern exposing the first conductive layer by etching the mask layer filling the first trench using a mixed gas including oxygen; selectively removing the first conductive layer using a stack of the photoresist film pattern and the mask pattern as a removal mask; forming a first metal gate filling the first trench and a second metal gate filling the second trench after removing the mask pattern and the photoresist film pattern.

In some embodiments, the mixed gas includes chlorine.

In some embodiments, a fraction of oxygen included in the mixed gas is a first fraction and a fraction of chlorine included in the mixed gas is a second fraction, and wherein the second fraction is greater than the first fraction.

In some embodiments, the mixed gas further includes helium.

In some embodiments, in the mixed gas, an amount of helium is greater than a sum of amounts of oxygen and chlorine.

In some embodiments, the mask layer is a bottom anti-reflective coating (BARC) layer.

In an aspect, a method for fabricating a semiconductor device comprises: forming a first in type active pattern and a second fin type active pattern on a substrate; forming a first trench crossing the first fin type active pattern on the first fin type active pattern and a second trench crossing the second fin type active pattern on the second fin type active pattern; forming a first TiN layer along sidewall surfaces and bottom surface of the first trench and a second TiN layer along sidewall surfaces and bottom surface of the second trench; forming a bottom anti-reflective coating (BARC) layer on the first conductive layer and second conductive layer, the BARC layer filling the first trench and the second trench; forming a photoresist film pattern on the BARC layer, the photoresist film pattern exposing the mask layer formed on the first conductive layer; forming a BARC pattern by removing the BARC layer filling the first trench using a mixed gas including oxygen, the BARC pattern exposing the first TiN layer; selectively removing the first TiN layer using the photoresist film pattern and the BARC pattern as a removal mask; and forming a first metal gate surrounding the first fin type active pattern by filling the first trench and a second metal gate surrounding the second fin type active pattern by filling the second trench after removing the BARC pattern and the photoresist film pattern.

In some embodiments, the BARC layer directly contacts the first TiN layer and the second TiN layer.

In some embodiments, the BARC layer filling the first trench is removed by reactive ion etching (RIE) using a mixed gas including oxygen and chlorine as a reaction gas.

In some embodiments, in the mixed gas, in the mixed gas, an amount of chlorine is greater than an amount of oxygen.

In some embodiments, the removing of the first TiN layer is performed using a stack of the photoresist film pattern and the BARC pattern as an etch mask.

In an aspect, a method of forming a semiconductor device comprises: forming a first trench and a second trench in an interlayer insulating layer on a substrate; forming a first conductive layer along sidewall surfaces and a bottom surface of the first trench and forming a second conductive layer along sidewall surfaces and a bottom surface of the second trench; forming a mask pattern on the second conductive layer and on the first conductive layer, the mask pattern filling the first trench and the second trench, the mask pattern being in direct contact with the first conductive layer, the mask layer comprising a bottom anti-reflective coating (BARC) layer; removing the mask layer filling the first trench by reactive ion etching using a gas including oxygen to form a mask pattern; and removing the first conductive layer using the mask pattern as a removal mask.

In some embodiments, the gas comprises a mixed gas and wherein the mixed gas further comprises chlorine.

In some embodiments, the mixed gas further comprises helium.

In some embodiments, in the mixed gas, an amount of chlorine is greater than an amount of oxygen.

In some embodiments, the method further comprises positioning a first gate dielectric layer between the substrate and the first conductive layer and positioning a second gate dielectric layer between the substrate and the second conductive layer.

In some embodiments, the method further comprises positioning the first gate dielectric layer between sidewalls of the first trench and the first conductive layer and positioning a second gate dielectric layer between sidewalls of the second trench and the second conductive layer.

### BRIEF DESCRIPTION OF THE DRAWINGS

The above and other features and advantages of the present inventive concepts will become more apparent by describing in detail embodiments thereof with reference to the attached drawings in which:

FIGS. 1 to 9 illustrate intermediate process steps for explaining a method for fabricating a semiconductor device according to a first embodiment of the present inventive concepts;

FIGS. 10 to 13 illustrate intermediate process steps for explaining a method for fabricating a semiconductor device according to a second embodiment of the present inventive concepts;

FIGS. 14 to 17 illustrate intermediate process steps for explaining a method for fabricating a semiconductor device according to a third embodiment of the present inventive concepts;

FIG. 18 is a block diagram of a memory card including a semiconductor device fabricated by a semiconductor device fabricating method according to some embodiments of the present inventive concepts;

FIG. 19 is a block diagram of an information processing system using a semiconductor device fabricated by a semiconductor device fabricating method according to some embodiments of the present inventive concepts; and

FIG. 20 is a block diagram of an electronic system including a semiconductor device fabricated by a semiconductor device fabricating method according to some embodiments of the present inventive concepts.

### DETAILED DESCRIPTION OF EMBODIMENTS

The present inventive concepts will now be described more fully hereinafter with reference to the accompanying drawings, in which preferred embodiments are shown. The inventive concepts may, however, be embodied in different forms and should not be construed as limited to the embodiments set forth herein. Rather, these embodiments are provided so that this disclosure will be thorough and complete, and will fully convey the scope to those skilled in the art. The same reference numbers indicate the same components throughout the specification. In the attached figures, the thickness of layers and regions is exaggerated for clarity.

It will be understood that when an element or layer is referred to as being “connected to,” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present. Like numbers refer to like elements throughout. As used herein, the term “and/or” includes any and all combinations of one or more of the associated listed items.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concepts.

The use of the terms “a” and “an” and “the” and similar referents in the context of describing the inventive concepts (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which the inventive concepts belong. It is noted that the use of any and all examples, or exemplary terms provided herein is intended merely to better illuminate the inventive concepts and is not a limitation on the scope of the inventive concepts unless otherwise specified. Further, unless defined otherwise, all terms defined in generally used dictionaries may not be overly interpreted.

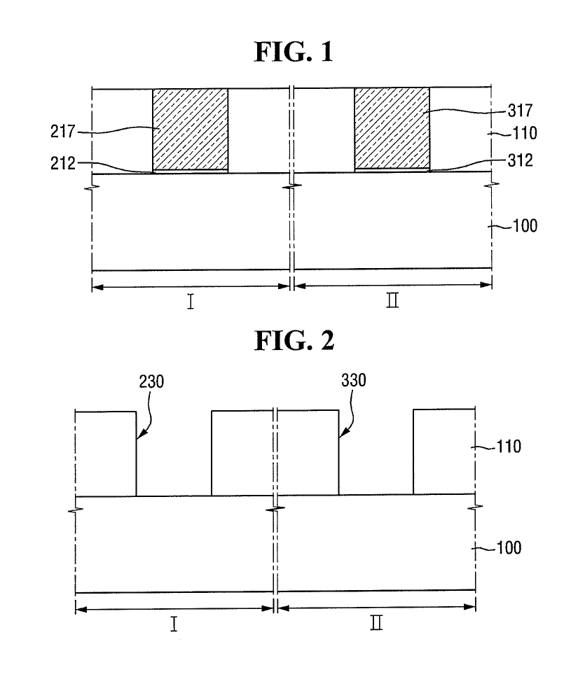

Hereinafter, a method for fabricating a semiconductor device according to a first embodiment of the present inventive concepts will be described with reference to FIGS. 1 to 9.

FIGS. 1 to 9 illustrate intermediate process steps for explaining a method for fabricating a semiconductor device according to a first embodiment of the present inventive concepts. For brevity, source/drain regions formed in a substrate, an isolation layer, such as a shallow trench isolation (STI) layer, and a spacer formed on sidewalls of a sacrificial gate are not illustrated in FIGS. 1 to 9.

Referring to FIG. 1, the substrate 100 may include a first region I and a second region II. The first region I and the second region II may be physically or electrically separated from each other or may be physically or electrically connected to each other.

In the method for fabricating a semiconductor device according to embodiments of the present inventive concepts, the first region I may be an NMOS region and the second region II may be a PMOS region.

In some embodiments, the substrate 100 may comprise any of a number of suitable substrates, including, for example, silicon or a silicon-on-insulator (SOI). Alternatively, the substrate 100 may comprise a silicon substrate, or a substrate made of one or more other materials selected from the group consisting of, for example, germanium, silicon germanium, indium antimonide, lead telluride compound, indium arsenide, indium phosphide, gallium arsenide, and gallium antimonide. However, aspects of the present inventive concepts are not limited thereto.

In some embodiments, a first dummy gate dielectric layer 212 and a first dummy gate 217 are formed on the first region I of the substrate 100. A second dummy gate dielectric layer 312 and a second dummy gate 317 are formed on the second region II of the substrate 100. The first dummy gate dielectric layer 212 is positioned between the substrate 100 and the first dummy gate 217 and the second dummy gate dielectric layer 312 is positioned between the substrate 100 and the second dummy gate 317.

Each of the first dummy gate dielectric layer 212 and the second dummy gate dielectric layer 312 may include, for example, one of silicon oxide (SiO₂), silicon oxynitride (SiON) and a combination thereof. In various embodiments, the first dummy gate dielectric layer 212 and the second dummy gate dielectric layer 312 may be formed by, for example, thermal treatment, chemical treatment, atomic layer deposition (ALD) or chemical vapor deposition (CVD), or other suitable formation process.

In some embodiments, the first dummy gate 217 and the second dummy gate 317 may include, for example, silicon (Si), specifically, poly Si, amorphous silicon (a-Si) and a combination thereof. The first dummy gate 217 and the second dummy gate 317 may both be absent of doping with impurities or may be doped with similar impurities. Alternatively, one of the first dummy gate 217 and the second dummy gate 317 may be doped and the other may not be doped. Alternatively, one of the first dummy gate 217 and the second dummy gate 317 may be doped with an n type material (e.g., arsenic, phosphorus, or the like) and the other may be doped with a p type material (e.g., boron, or the like).

In some embodiments, after the first dummy gate 217 and the second dummy gate 317 are formed, source/drain regions are formed at opposite sides of the first dummy gate 217 and the second dummy gate 317.

In some embodiments, an interlayer insulating layer 110 covering the first dummy gate 217 and the second dummy gate 317 is formed on the substrate 100. In some embodiments, the interlayer insulating layer 110 may include, for example, at least one of a low k material, oxide, nitride and oxynitride. Examples of the low k material may include flowable oxide (FOX), tonen silazene (TOSZ), undoped silica glass (USG), borosilica glass (BSG), phosphosilaca glass (PSG), borophosphosilica glass (BPSG), plasma enhanced tetra ethyl ortho silicate (PRTEOS), fluoride silicate glass (FSG), high density plasma (HDP), plasma enhanced oxide (PEOX), flowable CVD (FCVD), and combinations thereof, but aspects of the present inventive concepts are not limited thereto.

In some embodiments, the interlayer insulating layer 110 is planarized to expose top surfaces of the first dummy gate 217 and the second dummy gate 317. For example, the planarizing may be performed by chemical mechanical polishing (CMP), or other suitable planarization process.

Referring to FIG. 2, the first dummy gate 217 and the second dummy gate 317 are removed. After the first dummy gate 217 and the second dummy gate 317 are removed, the first dummy gate dielectric layer 212 and the second dummy gate dielectric layer 312 are removed, thereby forming a first trench 230 and a second trench 330. A top surface of the substrate 100 may be exposed by the first trench 230 and the second trench 330.

In other words, the interlayer insulating layer 110 including the first trench 230 and the second trench 330 is formed on the substrate 100. The first trench 230 is formed on the first region I and the second trench 330 is formed on the second region II. In the method for fabricating a semiconductor device according to the embodiment of the present inventive concepts, the first trench 230 is formed on the NMOS region and the second trench 330 is formed on the PMOS region.

In some embodiments, the first dummy gate 217 and the second dummy gate 317 may be removed by wet etching or dry etching. The wet etching will now be described in detail. The first dummy gate 217 and the second dummy gate 317 may be substantially removed by exposing the same to an aqueous solution containing a hydroxide source at a sufficiently high temperature for a sufficiently long time. The hydroxide source may include, but is not limited to, ammonium hydroxide or tetra alkyl ammonium hydroxide, such as tetra methyl ammonium hydroxide (TMAH).

In some embodiments, he first dummy gate dielectric layer 212 and the second dummy gate dielectric layer 312 may be removed by wet etching, dry etching and a combination thereof. An etching solution or etching gas may vary according to materials forming the first dummy gate dielectric layer 212 and the second dummy gate dielectric layer 312.

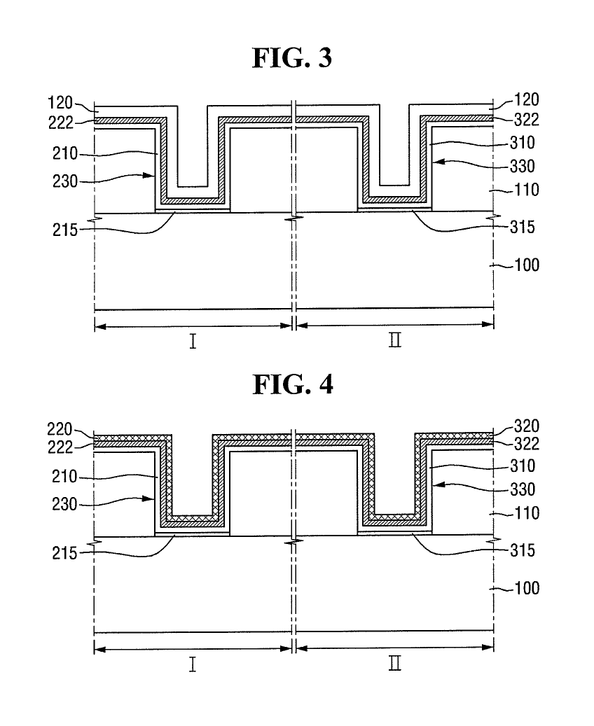

Referring to FIG. 3, in some embodiments, a first interface layer 215 and a second interface layer 315 are formed on the bottom surface of the first trench 230 and the bottom surface of the second trench 330, respectively.

In some embodiments, the first interface layer 215 and the second interface layer 315 may include silicon oxide. The first interface layer 215 and the second interface layer 315 may be formed using, for example, chemical oxidation, UV oxidation, or dual plasma oxidation.

A first dielectric layer 210 is conformally formed on the top surface of the interlayer insulating layer 110 and on the sidewall surfaces and bottom surface of the first trench 230. In addition, along with the first dielectric layer 210, a second dielectric layer 310 is conformally formed on the top surface of the interlayer insulating layer 110 and on the sidewall surfaces and bottom surface of the second trench 330. In detail, the first dielectric layer 210 and the second dielectric layer 310 are formed on the first interface layer 215 and the second interface layer 315, respectively.

The first dielectric layer 210 and the second dielectric layer 310 are simultaneously formed using, for example, CVD or ALD. In various embodiments, the first dielectric layer 210 and the second dielectric layer 310 may include high-k dielectric films made of, for example, one or more selected from the group consisting of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, but not limited thereto.

In some embodiments, a first lower conductive layer 222 and a second lower conductive layer 322 are formed on the first dielectric layer 210 and the second dielectric layer 310, respectively. The first lower conductive layer 222 and the second lower conductive layer 322 may be conformally formed along the first dielectric layer 210 and the second dielectric layer 310 using, for example, CVD or ALD, or other suitable formation process. In some embodiments, the first lower conductive layer 222 and the second lower conductive layer 322 may optionally be simultaneously formed and may include, for example, TiN layers.

In some embodiments, a capping layer 120 is formed on the first lower conductive layer 222 and the second lower conductive layer 322. After forming the capping layer 120, thermal treatment may be performed.

In some embodiments, the capping layer 120 may comprise, for example, one of poly silicon (poly Si), amorphous silicon (a-Si) and a combination thereof. When the thermal treatment is performed, the capping layer 120 may prevent thicknesses of the first interface layer 215 and the second interface layer 315 from increasing.

After the thermal treatment is performed, the capping layer 120 is removed, thereby exposing the first lower conductive layer 222 and the second lower conductive layer 322.

Referring to FIG. 4, a first conductive layer 220 is formed along the sidewall surfaces and bottom surfaces of the first trench 230 and a second conductive layer 320 is formed along the sidewall surfaces and bottom surfaces of the second trench 330.

In some embodiments, the first conductive layer 220 and the second conductive layer 320 are simultaneously formed along the top surface of the interlayer insulating layer 110, the sidewall surfaces and bottom surface of the first trench 230 and the sidewall surfaces and bottom surface of the second trench 330. The first conductive layer 220 and the second conductive layer 320 are conformally formed along the first lower conductive layer 222 and the second lower conductive layer 322. For example, in some embodiments, the first conductive layer 220 and the second conductive layer 320 may have thicknesses between 1 Å and 40 Å.

The first conductive layer 220 and the second conductive layer 320 may comprise p-type work function control layers. For example, the first conductive layer 220 and the second conductive layer 320 may include TiN layers. Alternatively, each of the first conductive layer 220 and the second conductive layer 320 may have a dual layer structure of a TaN layer and a TiN layer.

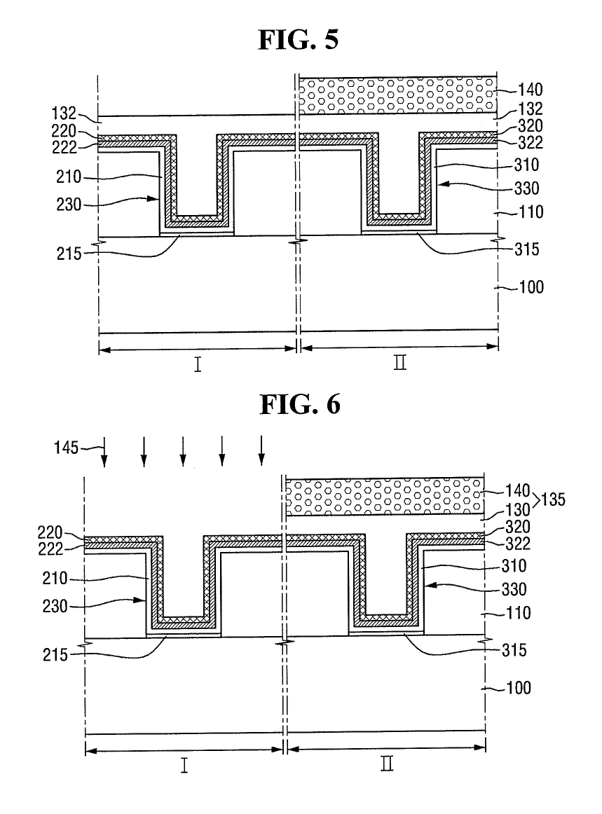

Referring to FIG. 5, in some embodiments, a mask layer 132 filling the first trench 230 and the second trench 330 is formed on the first conductive layer 220 and the second conductive layer 320. The mask layer 132 may also optionally be formed on the top surface of the interlayer insulating layer 110.

In some embodiments, the mask layer 132 may comprise a bottom anti-reflective coating (BARC) layer. In addition, the mask layer 132 may include a material having heightened gap-filling characteristics so as to efficiently fill the first trench 230 and the second trench 330.

In some embodiments, the mask layer 132 filling the first trench 230 and the second trench 330 is formed to make direct contact with the first conductive layer 220 and the second conductive layer 320.

A photoresist film pattern 140 can be formed on the mask layer 132. The photoresist film pattern 140 exposes the mask layer 132 formed on the first conductive layer 220, while covering the mask layer 132 formed on the second conductive layer 320.

That is to say, in some embodiments, the photoresist film pattern 140 exposes the first region I while covering the second region II. In addition, the photoresist film pattern 140 overlaps with the second conductive layer 320 while not overlapping with the first conductive layer 220.

Referring to FIG. 6, the mask layer 132 filling the first trench 230 is removed using the photoresist film pattern 140 as a mask of an etching process 145. Through the etching process 145, a mask pattern 130 is formed on the second conductive layer 320. The mask pattern 130 fills the second trench 330 and, in some embodiments, may comprise a BARC pattern.

In other words, the mask layer 132 formed on the first conductive layer 220 is removed from the first region I, thereby forming the mask pattern 130. The first conductive layer 220 is exposed by the mask pattern 130. That is to say, the first conductive layer 220 is exposed, and the second conductive layer 320 is covered by the mask pattern 130 and the photoresist film pattern 140. The mask pattern 130 and the photoresist film pattern 140 formed on the second conductive layer 320 constitute a stacked layer 135 to be used as an etch mask in a subsequent process.

In some embodiments, the mask layer 132 filling the first trench 230 may be removed by dry etching. The dry etching may be performed by, for example, reactive ion etching (RIE).

In an example of the dry etching for forming the mask pattern 130, the mask layer 132 filling the first trench 230 is etched using a mixed gas containing oxygen as an etch gas to then be removed. In some embodiments, the mixed gas used as the etching gas may include chlorine in addition to oxygen. In some embodiments, the mixed gas may further include helium.

In some embodiments, in the mixed gas used in the dry etching, a fraction of oxygen included in the mixed gas is a first fraction, a fraction of chlorine included in the mixed gas is a second fraction, and a fraction of helium included in the mixed gas is a third fraction. In the method for fabricating a semiconductor device according to the present inventive concepts, the second fraction of chlorine included in the mixed gas is greater than the first fraction of oxygen. For example, in the mixed gas, a ratio of the second fraction of chlorine to the first fraction of oxygen may have a value between about 1.1 and 7.

In some embodiments, in the mixed gas, the third fraction of helium may be greater than the first fraction of oxygen and greater than the second fraction of chlorine. In addition, in the mixed gas, an amount of helium may be greater than a sum of amounts of oxygen and chlorine.

In some embodiments, when the mask layer 132 filling the first trench 230 is removed by RIE, a potential bias may be applied to the substrate 100. For example, the bias applied to the substrate 100 may be in a range of 10 V to 300 V, but aspects of the present inventive concepts are not limited thereto. In addition, in the RIE process, power for generating plasma may be in a range of, for example, 50 W to 600 W, but aspects of the present inventive concepts are not limited thereto.

As another example of the dry etching for forming the mask pattern 130, the mask layer 132 filling the first trench 230 is etched using a mixed gas containing nitrogen and hydrogen as an etch gas to then be removed.

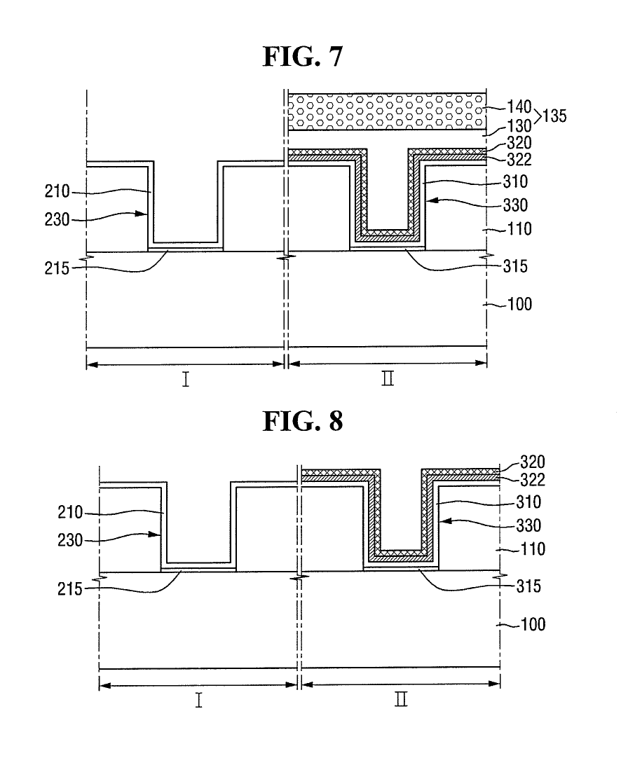

Referring to FIG. 7, the first conductive layer 220 is removed using the mask pattern 130 as a mask. After the first conductive layer 220 is removed, the first lower conductive layer 222 is removed, thereby exposing the first dielectric layer 210.

In some embodiments, the first conductive layer 220 and the first lower conductive layer 222 formed along the sidewall surfaces and bottom surface of the first trench 230 can be removed using a stacked layer 135 constituted by the mask pattern 130 and the photoresist film pattern 140 as an etch mask.

In some embodiments, the first conductive layer 220 and the first lower conductive layer 222 may be removed by, for example, wet etching. An etching solution used in wet etching may include, for example, hydrogen peroxide (H₂O₂), but aspects of the present inventive concepts are not limited thereto. In the course of removing the first conductive layer 220 and the first lower conductive layer 222, wet etching may be used to reduce the amount of damage applied to the first dielectric layer 210 to be exposed.

In the example, embodiment of FIG. 7, the first conductive layer 220 and the first lower conductive layer 222 are both removed to expose the first dielectric layer 210; however, aspects of the present inventive concepts are not limited thereto. That is to say, if the first conductive layer 220 has a dual layered structure consisting of a TaN layer and a TiN layer, the TiN layer included in the first conductive layer 220 may be removed while the TaN layer may not be removed. In such a case, the first dielectric layer 210 is not exposed and the first lower conductive layer 222 and the TaN layer included in the first conductive layer 220 may be conformally formed on the first dielectric layer 210.

Referring to FIG. 8, the mask pattern 130 and the photoresist film pattern 140 formed on the second conductive layer 320 are removed. The stacked layer 135 constituted by the mask pattern 130 and the photoresist film pattern 140 is removed, thereby exposing the second conductive layer 320.

For example, in some embodiments, the mask pattern 130 and the photoresist film pattern 140 may be ashed and stripped using a gas including hydrogen (H₂) and nitrogen (N₂).

The mask pattern 130 and the photoresist film pattern 140 are removed, thereby resulting in a structure in which the second dielectric layer 310, the second lower conductive layer 322 and the second conductive layer 320 are conformally formed sequentially on the top surface of the interlayer insulating layer 110 formed on the second region II, on the sidewall surfaces of the second trench 330 and on the second interface layer 315.

Unlike region II in which the second lower conductive layer 322 and the second conductive layer 320 remain on the second region II, in region I, the first dielectric layer 210 is conformally formed on the top surface of the interlayer insulating layer 110, on the sidewall surfaces of the first trench 230 and on the first interface layer 215.

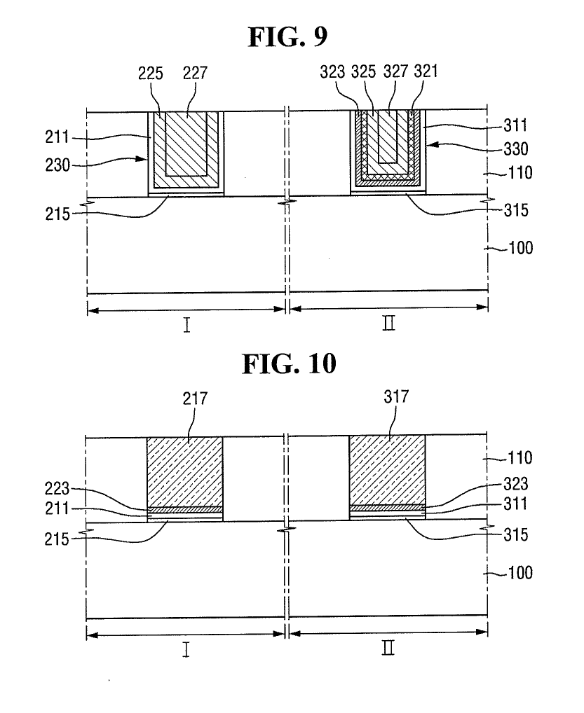

Referring to FIG. 9, first metal gates 225 and 227 are formed to fill the first trench 230 and second metal gates 325 and 327 are formed to fill the second trench 330.

In some embodiments, the first metal gates 225 and 227 may comprise a first lower metal gate 225 and a first upper metal gate 227 and the second metal gates 325 and 327 may include a second lower metal gate 325 and a second upper metal gate 327.

For example, in some embodiments, a lower metal gate layer and an upper metal gate layer are sequentially formed to sufficiently fill the first trench 230 and the second trench 330, and the upper metal gate layer, the lower metal gate layer, the first dielectric layer 210, the second dielectric layer 310, the second lower conductive layer 322 and the second conductive layer 320 are planarized to expose the top surface of the interlayer insulating layer 110.

Following planarization, the lower metal gate layer includes a first lower metal gate 225 formed in the first trench 230 and a second lower metal gate 325 formed in the second trench 330. In addition, by planarizing, the upper metal gate layer includes a first upper metal gate 227 formed in the first trench 230 and a second upper metal gate 327 formed in the second trench 330.

The first lower metal gate 225 and the second lower metal gate 325 formed by the planarizing may be conformally formed along the sidewall surfaces and bottom surfaces of the first trench 230 and the second trench 330, respectively.

Since the second conductive layer 320 formed on the top surface of the interlayer insulating layer 110 on the second region II is removed by the planarizing, the second conductive layer pattern 321 remains only in the second trench 330. The remaining second conductive layer pattern 321 formed only in the second trench 330 may have a thickness in a range of, for example, 1□ to 40□.

In some embodiments, the first metal gates 225 and 227 and the second metal gates 325 and 327 may have, for example, at least one of a structure in which a TiAl layer, a TiN layer and an Al layer are sequentially stacked, a structure in which a TiN layer, a TiAl layer, a TiN layer and an Al layer are sequentially stacked, a structure in which a TiAl layer, a TiN layer, a Ti layer and an Al layer are sequentially stacked, and a structure in which a TiN layer, a TiAl layer, a TiN layer, a Ti layer and an Al layer are sequentially stacked. In addition, first metal gates 225 and 227 and the second metal gates 325 and 327 may have, for example, at least one of a structure in which a TiN layer, a TiAlC layer, a TiN layer and a W layer are sequentially stacked, and a structure in which a TiN layer, a TiAl layer, a TiN layer and a W layer are sequentially stacked.

As a result, the first interface layer 215, the first gate dielectric layer 211 and the first metal gates 225 and 227 are formed in the first trench 230. On the other hand, the second interface layer 315, the second gate dielectric layer 311, the second lower conductive film pattern 323, the second conductive layer pattern 321 and the second metal gates 325 and 327 are formed in the second trench 330.

In the method for fabricating a semiconductor device according to the first embodiment of the present inventive concepts, the removing of the first conductive layer 220 is performed using only the photoresist film pattern 140 and the mask pattern 130. Additional layers are not required in the removing of the first conductive layer 220. Therefore, the method for fabricating a semiconductor device according to the first embodiment of the present inventive concepts can be simplified and the processing cost can be reduced. In addition, since additional layers are not provided in the removing of the first conductive layer 220, the thickness of a conductive layer pattern formed on the first region I and the second region II can be reduced.

A method for fabricating a semiconductor device according to a second embodiment of the present inventive concepts will be described with reference to FIGS. 10 to 13.

FIGS. 10 to 13 illustrate intermediate process steps for explaining a method for fabricating a semiconductor device according to a second embodiment of the present inventive concepts. For the sake of convenient explanation, the following description will focus on differences between the present and previous embodiments.

Referring to FIG. 10, a first dummy gate 217 is formed on a first region I of a substrate 100 and a second dummy gate 317 is formed on a second region II of the substrate 100.

Unlike in FIG. 1, the first interface layer 215 and the first gate dielectric layer 211 are interposed between the first dummy gate 217 and the substrate 100. In addition, the second interface layer 315 and the second gate dielectric layer 311 are interposed between the second dummy gate 317 and the substrate 100.

In addition, a first lower conductive film pattern 223 may be interposed between the first dummy gate 217 and the first gate dielectric layer 211 and a second lower conductive film pattern 323 may be interposed between the second dummy gate 317 and the second gate dielectric layer 311.

In some embodiments, the first dummy gate 217 and the second dummy gate 317 may comprise, for example, one of poly silicon (poly Si), amorphous silicon (a-Si) and a combination thereof. Each of the first dummy gate 217 and the second dummy gate 317 may perform the same function of the capping layer 120 described with reference to FIG. 3, but aspects of the present inventive concepts are not limited thereto.

In detail, an interface layer, a dielectric layer, a lower conductive layer and a capping layer are formed on the substrate 100 extending over the first region I and the second region II. After the dummy gate layer is formed, a thermal treatment is performed. In some embodiments, the interface layer may include a silicon oxide layer formed using, for example, chemical oxidation, UV oxidation, or dual plasma oxidation. The dielectric layer may include, for example, a high-k dielectric layer. The lower conductive layer may include, for example, a TiN layer.

After the thermal treatment is performed, the interface layer, the dielectric layer, the lower conductive layer and the capping layer are patterned. Through the patterning, the first interface layer 215, the first gate dielectric layer 211, the first lower conductive film pattern 223 and the first dummy gate 217 are sequentially formed on the first region I, and the first interface layer 215, the first gate dielectric layer 211, the first lower conductive film pattern 223 and the first dummy gate 217 are sequentially formed on the second region II.

In the method for fabricating a semiconductor device according to the second embodiment of the present inventive concepts, the capping layer is patterned, thereby forming the first dummy gate 217 and the second dummy gate 317, but aspects of the present inventive concepts are not limited thereto. In other words, after the thermal treatment is performed, the capping layer may be removed and a dummy gate layer may be additionally formed. The dummy gate layer may be patterned, thereby forming the first dummy gate 217 and the second dummy gate 317.

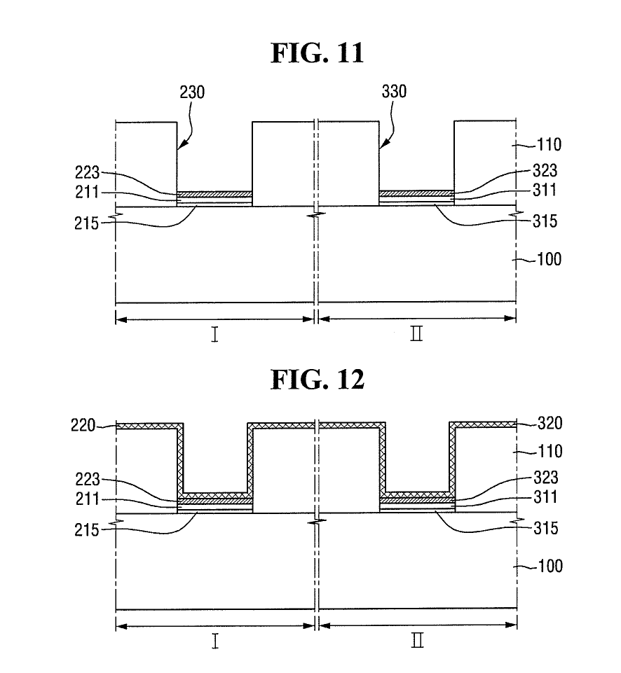

Referring to FIG. 11, in some embodiments, the first dummy gate 217 and the second dummy gate 317 are removed, thereby forming the first trench 230 and the second trench 330. The first trench 230 exposes the first lower conductive film pattern 223 and the second trench 330 exposes the second lower conductive film pattern 323.

Referring to FIG. 12, a first conductive layer 220 is formed along sidewall surfaces and bottom surface of the first trench 230 and a second conductive layer 320 is formed along sidewall surfaces and bottom surface of the second trench 330.

In other words, the first conductive layer 220 is formed on the top surface of the interlayer insulating layer 110, the sidewall surfaces of the first trench 230 and the top surface of the first gate dielectric layer 211. In addition, the second conductive layer 320 is formed on the top surface of the interlayer insulating layer 110, the sidewall surfaces of the second trench 330 and the top surface of the second gate dielectric layer 311. In detail, the first conductive layer 220 is formed on the top surface of the first lower conductive film pattern 223 and the second conductive layer 320 is formed on the top surface of the second lower conductive film pattern 323.

Thereafter, the first conductive layer 220 is removed through the steps described in FIGS. 5 to 8. When the first conductive layer 220 is removed, the first lower conductive film pattern 223 may also be removed.

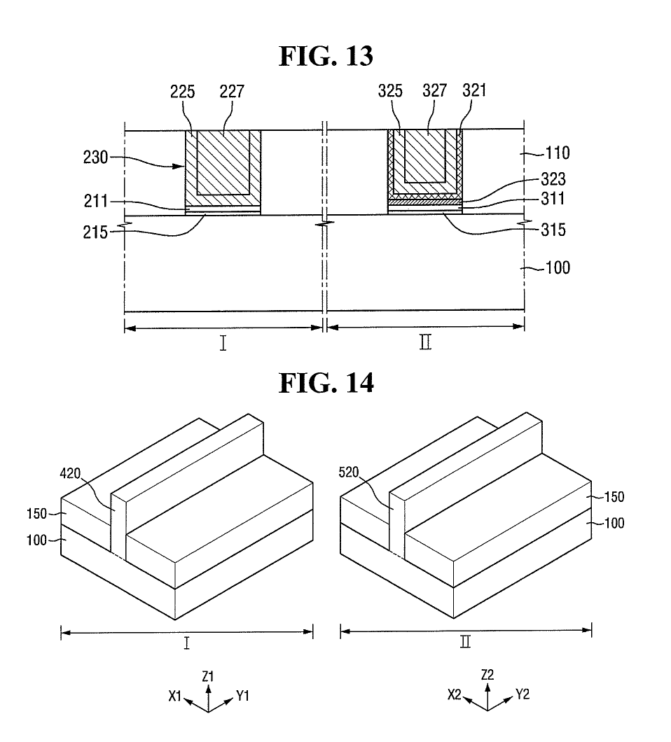

Referring to FIG. 13, first metal gates 225 and 227 are formed to fill the first trench 230 and second metal gates 325 and 327 are formed to fill the second trench 330, for example according to the manner described herein.

In some embodiments, the first interface layer 215 and the first gate dielectric layer 211 are sequentially stacked on the bottom surface of the first trench 230 on the first region I. The first lower metal gate 225 is formed along the sidewall surfaces and bottom surfaces of the first trench 230 on the first gate dielectric layer 211 and the first upper metal gate 227 is formed on the first lower metal gate 225.

A second interface layer 315, a second gate dielectric layer 311 and a second lower conductive film pattern 323 are sequentially stacked on the bottom surface of the second trench 330 on the second region II. A second conductive layer pattern 321 and a second lower metal gate 325 are formed along sidewall surfaces and bottom surface of the second trench 330 on the second lower conductive layer 322, and a second upper metal gate 327 is formed on the second lower metal gate 325.

A method for fabricating a semiconductor device according to a third embodiment of the present inventive concepts will be described with reference to FIGS. 14 to 17.

FIGS. 14 to 17 illustrate intermediate process steps for explaining a method for fabricating a semiconductor device according to a third embodiment of the present inventive concepts.

Referring to FIG. 14, a first fin type active pattern 420 and a second fin type active pattern 520 are formed on a substrate 100. The first fin type active pattern 420 is formed on a first region I and the second fin type active pattern 520 is formed on a second region II.

In some embodiments, the first fin type active pattern 420 and the second fin type active pattern 520 may extend lengthwise in a second direction Y1, Y2. The first fin type active pattern 420 and the second fin type active pattern 520 may portions of the substrate 100 and may include an epitaxial layer grown from the substrate 100. An isolation layer 150 may cover side surfaces of the first fin type active pattern 420 and the second fin type active pattern 520.

In some embodiments, the first fin type active pattern 420 and the second fin type active pattern 520 may include, for example, an element semiconductor material, such as silicon or germanium. In addition, the first fin type active pattern 420 and the second fin type active pattern 520 may include a compound semiconductor, such as a group IV-IV compound semiconductor, or a group III-V compound semiconductor. In detail, the first fin type active pattern 420 and the second fin type active pattern 520 may include the group IV-IV compound semiconductor, including, for example, a binary compound or a ternary compound, including two or more group IV elements, such as carbon (C), silicon (Si), germanium (Ge), or tin (Sn), or a compound prepared by doping a group IV element into the binary or ternary compound. In addition, the first fin type active pattern 420 and the second fin type active pattern 520 may include the group III-V compound semiconductor, including, for example, a binary compound, a ternary compound or a quaternary compound, prepared by combining at least one group III element of aluminum (Al), gallium (Ga) and indium (In) with at least one group V element of phosphorus (P), arsenic (As) and antimony (Sb).

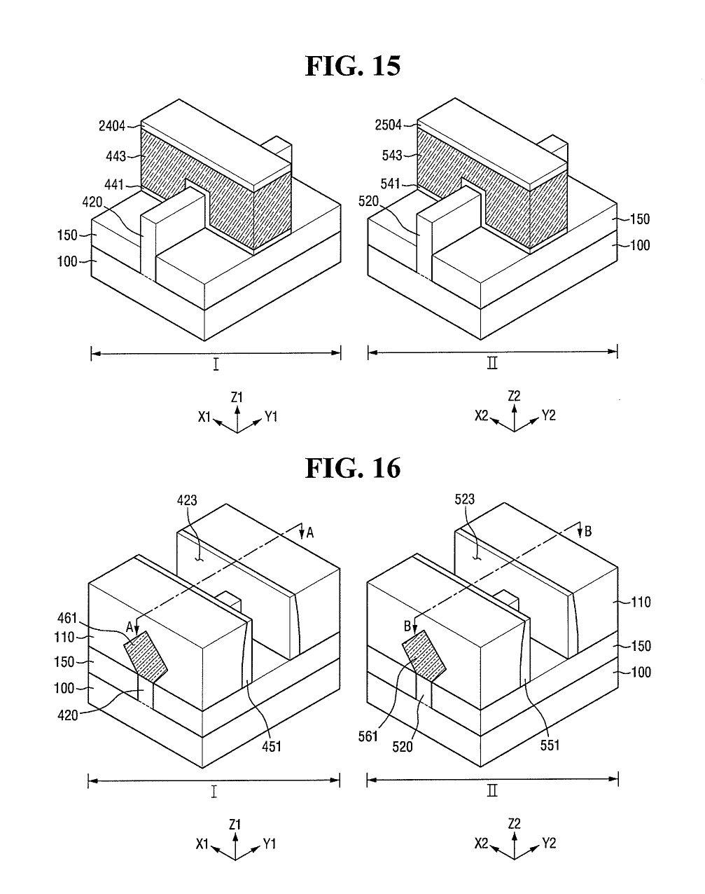

Referring to FIG. 15, etching is performed using the first hard mask pattern 2404 and the second hard mask pattern 2504, thereby forming a third dummy gate 443 extending in the first direction X1 while crossing the first fin type active pattern 420 and a fourth dummy gate 543 crossing the second fin type active pattern 520 and extending in the first direction X2.

A third dummy gate dielectric layer 441 is formed between the first fin type active pattern 420 and the third dummy gate 443, and a fourth dummy gate dielectric layer 541 is formed between the second fin type active pattern 520 and the fourth dummy gate 543.

In some embodiments, the third dummy gate dielectric layer 441 and the fourth dummy gate dielectric layer 541 may include, for example, one of silicon oxide (SiO₂), silicon oxynitride (SiON) and a combination thereof. The third dummy gate 443 and the fourth dummy gate 543 may include, for example, silicon (Si), specifically, poly Si, amorphous silicon (a-Si) and a combination thereof.

In the method for fabricating a semiconductor device according to the third embodiment of the present inventive concepts, the third dummy gate dielectric layer 441 and the fourth dummy gate dielectric layer 541 are formed, but aspects of the inventive concepts are not limited thereto. That is to say, like in the method for fabricating a semiconductor device according to the second embodiment, an interface layer and third and fourth gate dielectric layers including high-k materials may also be formed under the third dummy gate 443 and the fourth dummy gate 543.

Referring to FIGS. 15 to 17, the third dummy gate 443 and the third dummy gate dielectric layer 441 are removed, thereby forming a third trench 423 crossing the first fin type active pattern 420 on the first fin type active pattern 420. In addition, the fourth dummy gate 543 and the fourth dummy gate dielectric layer 541 are removed, thereby forming a fourth trench 523 crossing the second fin type active pattern 520 on the second fin type active pattern 520.

In detail, a first spacer 451 and a second spacer 551 are formed on sidewalls of the third dummy gate 443 and the fourth dummy gate 543, respectively. When the first spacer 451 and the second spacer 551 are formed, portions of the first fin type active pattern 420 and the second fin type active pattern 520 are removed, thereby forming recesses, respectively, the portions not overlapping with the third dummy gate 443 and the fourth dummy gate 543.

A first source/drain 461 and a second source/drain 561 are formed at opposite sides of the third dummy gate 443 and the fourth dummy gate 543, respectively.

An interlayer insulating layer 110 covering the first source/drain 461 and the second source/drain 561 is formed. Through a planarizing process, top surfaces of the third dummy gate 443 and the fourth dummy gate 543 are exposed.

The third dummy gate 443, the third dummy gate dielectric layer 441, the fourth dummy gate 543 and the fourth dummy gate dielectric layer 541 are removed, thereby forming a third trench 423 in the first region I and a fourth trench 523 in the second region II.

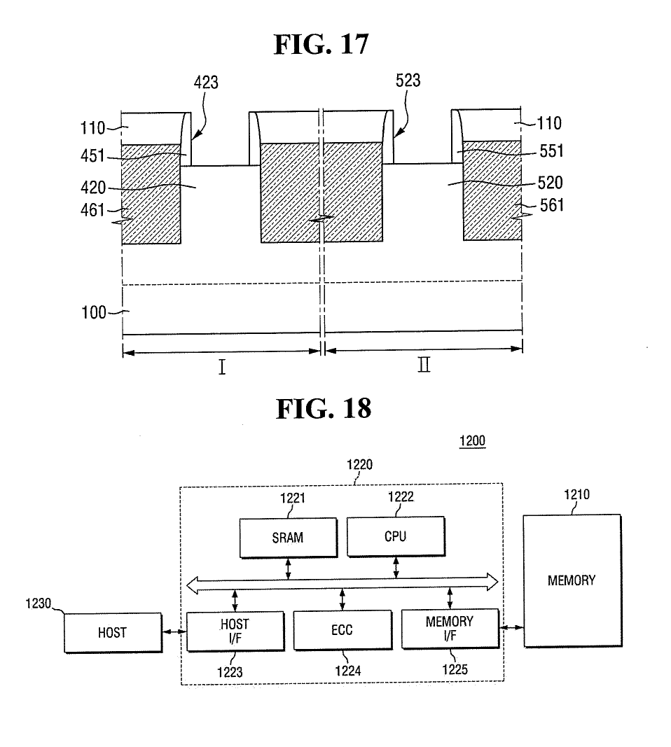

Process steps subsequent to the forming of the third trench 423 and the fourth trench 523, as shown in FIG. 17, are substantially the same as those of the method for fabricating the semiconductor device shown in FIGS. 3 to 9, and detailed descriptions thereof will not be made or will be briefly made.

A third interface layer, a third gate dielectric layer and a third metal gate are formed in the third trench 423 of the first region I. In addition, a fourth interface layer, a fourth gate dielectric layer, a fourth lower conductive layer pattern, a fourth conductive film pattern and a fourth metal gate are formed in the fourth trench 523 of the second region II. The third metal gate fills the third trench 423 to surround the first fin type active pattern 420 and the fourth metal gate fills the fourth trench 523 to surround the second fin type active pattern 520.

FIG. 18 is a block diagram of a memory card including a semiconductor device fabricated by a semiconductor device fabricating method according to some embodiments of the present inventive concepts.

Referring to FIG. 18, a memory 1210 including a semiconductor device according to various embodiments of the present inventive concepts may be employed to the memory card 1200. The memory card 1200 may include a memory controller 1220 controlling data exchange between a host 1230 and a memory 1210. An SRAM 1221 may be used as a working memory of a central processing unit 1222. A host interface 1223 may include a protocol for exchanging data to allow the host 1230 to access the memory card 1200. An error correction code 1224 may be used to detect and correct an error of data read from the memory 1210. A memory interface 1225 may interface with the memory 1210. The central processing unit 1222 may perform the overall control operation associated with the data exchange of the memory controller 1220.

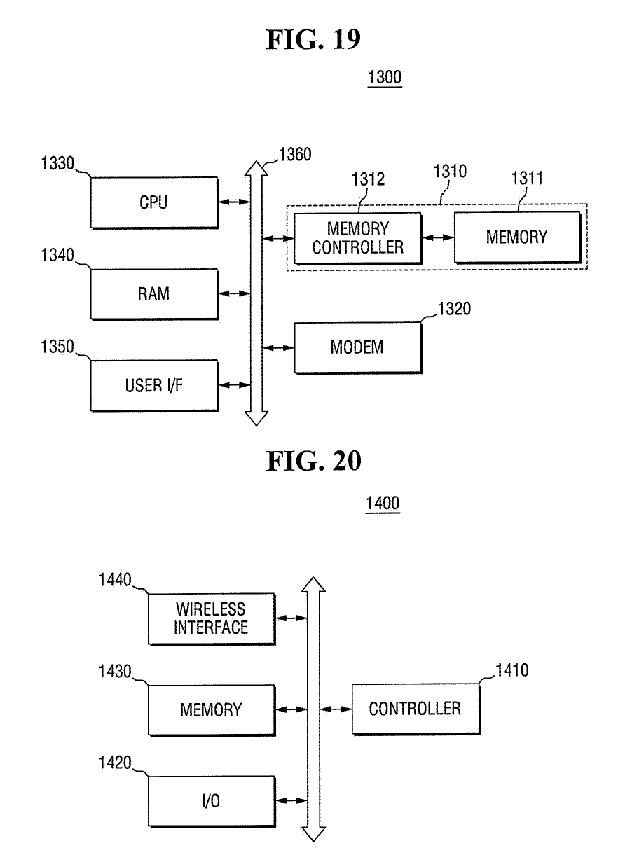

FIG. 19 is a block diagram of an information processing system using a semiconductor device fabricated by a semiconductor device fabricating method according to some embodiments of the present inventive concepts.

Referring to FIG. 19, in some embodiments, the information processing system 1300 may include a memory system 1310 including a semiconductor device according to various embodiments of the present inventive concepts. The information processing system 1300 may include a memory system 1310, a modem 1320, a central processing unit 1330, an RAM 1340 and a user interface 1350, which are electrically connected to a system bus 1360. The memory system 1310 may include a memory 1311 and a memory controller 1312 and may have substantially the same configuration as the memory card 1200 shown in FIG. 18. Data processed by the central processing unit 1330 or externally applied data may be stored in the memory system 1310. The information processing system 1300 may be applied to a memory card, a solid state disk (SSD), a camera image sensor and other various chip sets. For example, the memory system 1310 may be configured to employ the SSD. In this case, the information processing system 1300 may process a large amount of data in a stable, reliable manner.

FIG. 20 is a block diagram of an electronic system including a semiconductor device fabricated by a semiconductor device fabricating method according to some embodiments of the present inventive concepts.

Referring to FIG. 20, the electronic device 1400 may include a semiconductor device according to various embodiments of the present inventive concepts. The electronic device 1400 may be applied to a wireless communication device (for example, a personal digital assistant (PDA), a notebook computer, a portable computer, a web tablet, a wireless phone, and/or a wireless digital music player) or any type of electronic device capable of transmitting and/or receiving information in a wireless environment.

The electronic device 1400 may include a controller 1410, an input/output device (I/O) 1420, a memory 1430, and a wireless interface 1440. Here, the memory 1430 may include a semiconductor device according to various embodiments of the present inventive concepts. The controller 1410 may include a microprocessor, a digital signal processor, and a processor capable of performing functions similar to these components. The memory 1430 may be used to store commands processed by the controller 1410 (or user data). The wireless interface 1440 may be used to exchange data through a wireless data network. The wireless interface 1440 may include an antenna or a wired/wireless transceiver. For example, the electronic device 1400 may use a third generation communication system protocol, such as CDMA, GSM, NADC, E-TDMA, WCDMA, CDMA2000, or the like.

While the present inventive concepts have been particularly shown and described with reference to exemplary embodiments thereof, it will be understood by those of ordinary skill in the art that various changes in form and details may be made therein without departing from the spirit and scope of the present inventive concepts as defined by the following claims. It is therefore desired that the present embodiments be considered in all respects as illustrative and not restrictive, reference being made to the appended claims rather than the foregoing description to indicate scope.

1. A method for fabricating a semiconductor device, the method comprising:
forming an interlayer insulating layer on a substrate, the interlayer insulating layer including a first trench and a second trench;
forming a first conductive layer along sidewall surfaces and a bottom surface of the first trench and forming a second conductive layer along sidewall surfaces and a bottom surface of the second trench;
forming a mask pattern on the second conductive layer, the mask pattern filling the second trench and comprising a bottom anti-reflective coating (BARC); and
removing the first conductive layer using the mask pattern.

2. The method of claim 1, wherein the forming of the mask pattern comprises forming a mask layer filling the first trench and the second trench on the first conductive layer and the second conductive layer, and removing the mask layer filling the first trench using a mixed gas including oxygen and chlorine.

3. The method of claim 2, wherein the forming of the mask pattern comprises removing the mask layer filling the first trench by reactive ion etching (RIE).

4. The method of claim 2, wherein the first conductive layer and the second conductive layer directly contacts the mask layer.

5. The method of claim 2, wherein the forming of the mask pattern comprises forming a photoresist film pattern on the mask layer, the photoresist film pattern on the second conductive layer and not on the first conductive layer, and removing the mask layer filling the first trench using the photoresist film pattern.

6. The method of claim 5, wherein the removing of the first conductive layer comprises removing the first conductive layer formed along the sidewall surfaces and bottom surface of the first trench using a stack of the photoresist film pattern and the mask pattern.

7. The method of claim 1, wherein the forming of the mask pattern comprises forming the mask pattern filling the first trench and the second trench on the first conductive layer and the second conductive layer, and removing the mask pattern filling the first trench using a mixed gas including oxygen and chlorine.

8. The method of claim 1, wherein the first trench is formed on an NMOS region and the second trench is formed on a PMOS region.

9. The method of claim 8, wherein the first conductive layer and the second conductive layer comprise TiN.

10. The method of claim 1, wherein the forming of the first conductive layer and the second conductive layer comprises simultaneously forming the first conductive layer and the second conductive layer along a top surface of the interlayer insulating layer, sidewall surfaces and bottom surface of the first trench and sidewall surfaces and bottom surface of the second trench.

11. The method of claim 1, wherein the forming of the first trench and the second trench comprises forming a first dummy gate and a second dummy gate on the substrate, the first dummy gate and the second dummy gate formed on a first region and a second region of the substrate, respectively, forming the interlayer insulating layer covering the first dummy gate and the second dummy gate on the substrate, exposing the first dummy gate and the second dummy gate by planarizing the interlayer insulating layer, and removing the first dummy gate and the second dummy gate.

12. The method of claim 11, wherein a first gate dielectric layer is positioned between the first dummy gate and the substrate, and a second gate dielectric layer is positioned between the second dummy gate and the substrate.

13. The method of claim 12, wherein the forming of the first conductive layer comprises forming the first conductive layer on the top surface of the interlayer insulating layer, the sidewall surface of the first trench and the top surface of the first gate dielectric layer, and the forming of the second conductive layer comprises forming the second conductive layer on the top surface of the interlayer insulating layer, the sidewall surface of the second trench and the top surface of the second gate dielectric layer.

14. The method of claim 12, after the removing of the first dummy gate and the second dummy gate, further comprising removing the first gate dielectric layer and the second gate dielectric layer, and before the forming of the first conductive layer and the second conductive layer, further comprising forming a dielectric layer on the top surface of the interlayer insulating layer, the sidewall surfaces and bottom surface of the first trench and the sidewall surfaces and bottom surface of the second trench.

15. A method for fabricating a semiconductor device, the method comprising:
forming an interlayer insulating layer on a substrate, the interlayer insulating layer including a first trench and a second trench;
forming a first conductive layer along sidewall surfaces and a bottom surface of the first trench and forming a second conductive layer along sidewall surfaces and bottom surface of the second trench;
forming a mask layer on the first conductive layer and the second conductive layer, the mask layer filling the first trench and the second trench;
forming a photoresist film pattern on the mask layer, the photoresist film pattern exposing the mask layer formed on the first conductive layer;
forming a mask pattern exposing the first conductive layer by etching the mask layer filling the first trench using a mixed gas including oxygen;
selectively removing the first conductive layer using a stack of the photoresist film pattern and the mask pattern as a removal mask;
forming a first metal gate filling the first trench and a second metal gate filling the second trench after removing the mask pattern and the photoresist film pattern.

16. The method of claim 15, wherein the mixed gas includes chlorine.

17. The method of claim 16, wherein a fraction of oxygen included in the mixed gas is a first fraction and a fraction of chlorine included in the mixed gas is a second fraction, and wherein the second fraction is greater than the first fraction.

18. The method of claim 16, wherein the mixed gas further includes helium.

19. The method of claim 18, wherein in the mixed gas, an amount of helium is greater than a sum of amounts of oxygen and chlorine.

20. The method of claim 15, wherein the mask layer is a bottom anti-reflective coating (BARC) layer.

21. A method for fabricating a semiconductor device, the method comprising:
forming a first fin type active pattern and a second fin type active pattern on a substrate;
forming a first trench crossing the first fin type active pattern on the first fin type active pattern and a second trench crossing the second fin type active pattern on the second fin type active pattern;
forming a first TiN layer along sidewall surfaces and bottom surface of the first trench and a second TiN layer along sidewall surfaces and bottom surface of the second trench;
forming a bottom anti-reflective coating (BARC) layer on the first conductive layer and second conductive layer, the BARC layer filling the first trench and the second trench;
forming a photoresist film pattern on the BARC layer, the photoresist film pattern exposing the mask layer formed on the first conductive layer;
forming a BARC pattern by removing the BARC layer filling the first trench using a mixed gas including oxygen, the BARC pattern exposing the first TiN layer;
selectively removing the first TiN layer using the photoresist film pattern and the BARC pattern as a removal mask; and
forming a first metal gate surrounding the first fin type active pattern by filling the first trench and a second metal gate surrounding the second fin type active pattern by filling the second trench after removing the BARC pattern and the photoresist film pattern.

22. The method of claim 21, wherein the BARC layer directly contacts the first TiN layer and the second TiN layer.

23. The method of claim 21, wherein the BARC layer filling the first trench is removed by reactive ion etching (RIE) using a mixed gas including oxygen and chlorine as a reaction gas.

24. The method of claim 23, wherein in the mixed gas, in the mixed gas, an amount of chlorine is greater than an amount of oxygen.

25. (canceled)

26. A method of forming a semiconductor device comprising:
forming a first trench and a second trench in an interlayer insulating layer on a substrate;
forming a first conductive layer along sidewall surfaces and a bottom surface of the first trench and forming a second conductive layer along sidewall surfaces and a bottom surface of the second trench;
forming a mask pattern on the second conductive layer and on the first conductive layer, the mask pattern filling the first trench and the second trench, the mask pattern being in direct contact with the first conductive layer, the mask layer comprising a bottom anti-reflective coating (BARC) layer;
removing the mask layer filling the first trench by reactive ion etching using a gas including oxygen to form a mask pattern; and
removing the first conductive layer using the mask pattern as a removal mask.

27. The method of claim 26 wherein the gas comprises a mixed gas and wherein the mixed gas further comprises chlorine.

28. The method of claim 27 wherein the mixed gas further comprises helium.

29. The method of claim 27, wherein in the mixed gas, an amount of chlorine is greater than an amount of oxygen.

30. The method of claim 26 further comprising positioning a first gate dielectric layer between the substrate and the first conductive layer and positioning a second gate dielectric layer between the substrate and the second conductive layer.

31. The method of claim 30 further comprising positioning the first gate dielectric layer between sidewalls of the first trench and the first conductive layer and positioning a second gate dielectric layer between sidewalls of the second trench and the second conductive layer.
